(19) United States
(12) Patent Application Publication
(10) Pub. No.: US 2008/0099696 A1
(43) Pub. Date: May 1, 2008

(54) Shaped apertures in an ion implanter

(75) Inventors: Geoffrey Ryding, Manchester, MA (US); Takao Sakase, Rowley, MA (US); Marvin Farley, Ipswich, MA (US); Steven Hays, Rowley, MA (US)

Correspondence Address: Robert W. MULCAHY;Applied Materials, Inc., Box 450A, Santa Clara, CA, 95052, US

(73) Assignee: APPLIED MATERIALS, INC.

(21) Appl. No.: 11/589,767

(22) Filed: Oct. 31, 2006

(51) Int. Cl. H01J 37/317

(52) U.S. Cl. 250/492.21

(57) ABSTRACT

This invention relates to shaped apertures in an ion implanter that may act to clip an ion beam and so adversely affect uniformity of an implant. In particular, the present invention finds application in ion implanters that employ scanning of a substrate to be implanted relative to the ion beam such that the ion beam traces a raster pattern over the substrate. An ion implanter is provided comprising: a substrate scanner arranged to scan a substrate repeatedly through an ion beam in a scanning direction substantially transverse to the ion beam path, thereby forming a series of scan lines across the substrate; and an aperture plate having provided therein an aperture positioned on the ion beam path upstream of the substrate scanner, and wherein the aperture is defined in part by an inwardly-facing projection.

### FIELD OF THE INVENTION

This invention relates to shaped apertures in an ion implanter that may act to clip an ion beam and so adversely affect uniformity of an implant. In particular, the present invention finds application in ion implanters that employ scanning of a substrate to be implanted relative to the ion beam such that the ion beam traces a raster pattern over the substrate.

### BACKGROUND OF THE INVENTION

Ion implanters are well known and generally conform to a common design as follows. An ion source produces a mixed beam of ions from a precursor gas or the like. Only ions of a particular species are usually required for implantation in a substrate, for example a particular dopant for implantation in a semiconductor wafer. The required ions are selected from the mixed ion beam using a mass-analysing magnet in association with a mass-resolving slit. Hence, an ion beam containing almost exclusively the required ion species emerges from the mass-resolving slit to be transported to a process chamber where the ion beam is incident on a substrate held in place in the ion beam path by a substrate holder.

Ion beams often have approximately circular cross-sectional profiles and are much smaller than the substrate to be implanted. In order to implant the entire surface of the substrate, the ion beam and substrate must be moved relative to one another such that the ion beam scans the entire substrate surface. This may be achieved by (a) deflecting the ion beam to scan across the substrate that is held in a fixed position, (b) mechanically moving the substrate whilst keeping the ion beam path fixed or (c) a combination of deflecting the ion beam and moving the substrate.

Our U.S. Pat. No. 6,956,223 describes an ion implanter of the general design described above. While some steering of the ion beam is possible, the ion implanter is operated such that ion beam follows a fixed path during implantation. Instead, a substrate is held in a substrate holder that is scanned along two orthogonal axes to cause the ion beam to trace over the wafer following a raster pattern like that illustrated in FIG. 1.

The substrate is moved continuously in a single direction (the fast-scan direction) to complete a first scan line. The substrate is then stepped up a short distance orthogonally (in the slow-scan direction), and a second line is then scanned. This combination of reciprocating scan lines and indexed stepwise movement results in scanning of the whole surface of the substrate through the ion beam. The pitch of the scan lines is chosen to be less than the height of the ion beam, such that successive scan lines overlap. The pitch is carefully chosen with reference to the ion beam profile to ensure uniformity of implant: typical profiles see most of the ion beam current at the centre of the ion beam, and the current tails away towards the edges of the ion beam. An ideal profile would be a Gaussian, although such profiles are rarely seen in practice. Overlapping adjacent scan lines may be used to ensure uniform implants due to the smoothly varying profile.

Further improvements may be made to improve the uniformity of implants made using such raster scans. For example, multiple passes over the substrate may be made and interlacing may be effected (e.g. make a first pass implanting the first, fifth, ninth, etc. scan lines, then make a second pass implanting the second, sixth, tenth, etc. scan lines, then make a third pass, etc.). Also, the wafer may be rotated between passes, for example four passes are made with a 90° twist of the substrate between each pass in a quad implant. Our U.S. patent application Ser. No. 11/527,594 provides more details of such scanning techniques.

### SUMMARY OF THE INVENTION

It has been realised that the use of overlapping scan lines to ensure uniformity of implant is particularly prone to a problem. Specifically, the success of this technique relies on a smoothly varying profile to the ion beam in the direction transverse to the fast-scan speed across the substrate. Preferably, the variation is a Gaussian variation. However, ion implanters often employ rectangular apertures along the ion beam's path. It has been appreciated that, should the ion beam clip straight edges of the aperture, it will lose its smooth variation at those clipped edges. In particular, this is severe where the ion beam is clipped by an edge extending in the same direction as the fast scan direction as this leads to a sharp edge on the ion beam that is effectively drawn along the substrate. Thus, a hard edge is formed on the scan lines across the substrate where they overlap, leading to periodic sharp jumps in dose level as you travel across the substrate in the slow scan direction (i.e. as you traverse across the scan lines). This is true irrespective of whether the substrate is scanned or the ion beam is scanned. The effect is described in more detail below with reference to FIGS. 5 to 7.

Against the above background, and from a first aspect, the present invention provides an ion implanter comprising: an ion source arranged to generate an ion beam; ion beam optics arranged to guide the ion beam along an ion beam path; a substrate scanner arranged to scan a substrate relative to the ion beam in a scanning direction substantially transverse to the ion beam path such that the ion beam forms a series of scan lines across the substrate; and an aperture plate having provided therein an aperture defined by internal edges of the aperture plate, the aperture being positioned on the ion beam path upstream of the substrate scanner, and wherein the aperture is defined in part by an edge extending generally in the scanning direction provided with at least one inwardly-facing projection.

The present application may find application in an ion implanter that uses deflection of the ion beam to effect scanning in the scanning direction. Such scanning is generally performed after the ion beam has cleared the final aperture on the ion beam path, i.e. the ion beam follows a fixed path through the apertures and then is scanned. Nonetheless, if the ion beam is clipped upstream by an aperture, the resulting ion beam profile will have a harder edge where it was clipped that may lead to a loss of uniformity in an implant. Accordingly, it is still useful to use an aperture plate as shaped above.

However, the present invention is primarily intended for use in ion implanters that use mechanical scanning of the substrate relative to a fixed ion beam. The problem of ion beam clipping is often worse in such implanters because the final apertures tend to be positioned closer to the substrate than for scanned-beam implanters, meaning that any angular variation in the ion beam has less chance to smooth any hard edges imposed by clipping. Hence, preferably the substrate scanner is arranged to scan the substrate repeatedly through the ion beam in the scanning direction substantially transverse to the ion beam path such that the ion beam forms a series of scan lines across the substrate.

Provision of the inwardly facing projection is advantageous as it addresses the problems of a sharp edge being formed if the ion beam clips that edge. This is because the inwardly facing projection must provide an edge that extends transversely to the scanning direction. Hence, a single edge extending along the scanning direction is avoided. For example, the projection may simply be a tooth that sees a step introduced to the edge that extends in the scanning direction. This alleviates the problem in that there will then be two sharp edges introduced to the ion beam that average as the ion beam is traced across the substrate (i.e. the substrate sees dosing contributions from both edges). As an improvement, the projection may not be a tooth, but may comprise a series of steps.

Clearly, it is better to present a smoothly varying projection such that contributions to the ion beam's edge may be made at many positions transverse to the scanning direction. For example, the projection may be arcuate or v-shaped, thereby leading to a better smoothed edge to the ion beam should it clip that edge. Another contemplated shape is for the projection to have sinuous edges. For example, the projection may be generally v-shaped, but have sides that are each s-shaped (i.e. in the shape of an “s” or the mirror image of an “s”). These sides may have the shape of the side of a Gaussian peak, preferably with the peak extending in the fast-scan direction. Put another way, if the projection is provided on a top or bottom edge, the sides may be shaped like the side of a Gaussian peak lying on its side. Both sides may have such a shape such that the projection is symmetrical and adopts the shape of an onion dome, or at least the tapering top half of an onion dome.

Preferably, the projection is provided centrally on the edge. This is advantageous as the projection is more likely to act on the centreline of the ion beam where the current will be greater.

Rather than the edge comprising a single projection, it may comprise a plurality of inwardly-facing projections. These projections may all be alike, or they may differ. For example, the edge may comprise a plurality of like onion domes or the edge may comprise a plurality of teeth that extend inwardly to different depths.

Generally, an aperture will be defined by two edges that extend generally in the scanning direction. If so, both edges are preferably provided with at least one inwardly-facing projection. Optionally, the edges are mirror images.

From a second aspect, the present invention resides in a method of improving uniformity in an implant made by an ion implanter comprising an ion source arranged to generate an ion beam, ion beam optics arranged to guide the ion beam along an ion beam path, a substrate scanner arranged to scan a substrate relative to the ion beam in a scanning direction substantially transverse to the ion beam path such that the ion beam forms a series of scan lines across the substrate, and an aperture plate having provided therein an aperture defined by internal edges of the aperture plate, the aperture being positioned on the ion beam path upstream of the substrate scanner, the method comprising providing the aperture plate with an edge that partly defines the aperture, and that extends generally in the scanning direction but that is provided with at least a portion that extends in a direction other than the scanning direction.

From this aspect of the invention, other shapes to the aperture edge are contemplated when trying to address the problem of uniformity in an implant where the ion beam may clip the aperture edge. For example, circular, ovoid, diamond shaped or hexagonal shaped apertures may be used to address uniformity. While not being as effective as an inwardly-facing projection acting on the centreline of an ion beam where the current is highest, these other shapes nonetheless act to smooth the edge if the ion beam is clipped. The method may also comprise providing the edge with the portion that extends over 25%, 50%, 75% or 90% of the length of the edge. Optionally, the portion may be positioned centrally.

Other preferred features are defined by the appended claims.

### BRIEF DESCRIPTION OF THE DRAWINGS

Embodiments of the present invention, along with aspects of the prior art, will now be described with reference to the accompanying drawings, of which:

FIG. 1 illustrates a raster scan pattern of an ion beam across a wafer;

FIG. 2 shows a conventional ion implanter;

FIG. 3a shows a conventional aperture plate with an ion beam passing through the aperture without being clipped;

FIG. 3b is an ion beam profile taken along line III-III of FIG. 3a, on the downstream side of the aperture plate;

FIG. 4a shows a conventional aperture plate with an ion beam passing through the aperture such that its top and bottom are clipped;

FIG. 4b is an ion beam profile taken along line IV-IV of FIG. 4a, on the downstream side of the aperture plate;

FIG. 5a shows schematically an ion beam being scanned across a substrate;

FIG. 5b is an ion beam profile taken along line V-V of FIG. 5a to show a hypothetical top-hat current profile;

FIG. 6a shows schematically an ion beam being scanned across a substrate twice to form two overlapping scan lines;

FIG. 6b shows the dose received by the substrate of FIG. 6a as a function of position across the scan lines;

FIG. 7a shows schematically an ion beam being scanned across a substrate twice to form two separated scan lines;

FIG. 7b shows the dose received by the substrate of FIG. 7a as a function of position across the scan lines;

FIG. 8 shows an aperture plate according to a first embodiment of the present invention;

FIG. 9 shows an aperture plate according to a second embodiment of the present invention;

FIG. 10 shows an aperture plate according to a third embodiment of the present invention;

FIG. 11 shows an aperture plate according to a fourth embodiment of the present invention;

FIG. 12 shows an aperture plate according to a fifth embodiment of the present invention;

FIG. 13 shows an aperture plate according to a sixth embodiment of the present invention;

FIG. 14 shows an aperture plate according to a seventh embodiment of the present invention;

FIG. 15 shows an aperture plate according to an eighth embodiment of the present invention; and

FIG. 16 shows an aperture plate according to a ninth embodiment of the present invention.

### DETAILED DESCRIPTION OF THE INVENTION

FIG. 2 shows a known ion implanter 10 for implanting ions in substrates 12, and that may be used to implement the present invention. Ions are generated by the ion source 14 to be extracted and follow an ion path 34 that passes, in this embodiment, through a mass analysis stage 30. Ions of a desired mass are selected to pass through a mass-resolving slit 32 and then to strike the semiconductor substrate 12.

The ion implanter 10 contains an ion source 14 for generating an ion beam of a desired species that is located within a vacuum chamber 15 evacuated by pump 24. The ion source 14 generally comprises an arc chamber 16 containing a cathode 20 located at one end thereof. The ion source 14 may be operated such that an anode is provided by the walls 18 of the arc chamber 16. The cathode 20 is heated sufficiently to generate thermal electrons.

Thermal electrons emitted by the cathode 20 are attracted to the anode, the adjacent chamber walls 18 in this case. The thermal electrons ionise gas molecules as they traverse the arc chamber 16, thereby forming a plasma and generating the desired ions.

The path followed by the thermal electrons may be controlled to prevent the electrons merely following the shortest path to the chamber walls 18. A magnet assembly 46 provides a magnetic field extending through the arc chamber 16 such that thermal electrons follow a spiral path along the length of the arc chamber 16 towards a counter-cathode 44 located at the opposite end of the arc chamber 16.

A gas feed 22 fills the arc chamber 16 with the species to be implanted or with a precursor gas species. The arc chamber 16 is held at a reduced pressure within the vacuum chamber 15. The thermal electrons travelling through the arc chamber 16 ionise the gas molecules present in the arc chamber 16 and may also crack molecules. The ions (that may comprise a mixture of ions) created in the plasma will also contain trace amounts of contaminant ions (e.g. generated from the material of the chamber walls 18).

Ions from within the arc chamber 16 are extracted through an exit aperture 28 provided in a front plate of the arc chamber 16 using a negatively-biased (relative to ground) extraction electrode 26. A potential difference is applied between the ion source 14 and the following mass analysis stage 30 by a power supply 21 to accelerate extracted ions, the ion source 14 and mass analysis stage 30 being electrically isolated from each other by an insulator (not shown). The mixture of extracted ions are then passed through the mass analysis stage 30 so that they pass around a curved path under the influence of a magnetic field. The radius of curvature travelled by any ion is determined by its mass, charge state and energy, and the magnetic field is controlled so that, for a set beam energy, only those ions with a desired mass to charge ratio and energy exit along a path coincident with the mass-resolving slit 32. The emergent ion beam is then transported to the process chamber 40 where the target is located, i.e. the substrate 12 to be implanted or a beam stop 38 when there is no substrate 12 in the target position. In other modes, the beam may also be accelerated or decelerated using a lens assembly 49 positioned between the mass analysis stage 30 and the substrate position.

The substrate 12 is mounted on a substrate holder 36, substrates 12 being successively transferred to and from the substrate holder 36, for example through a load lock (not shown).

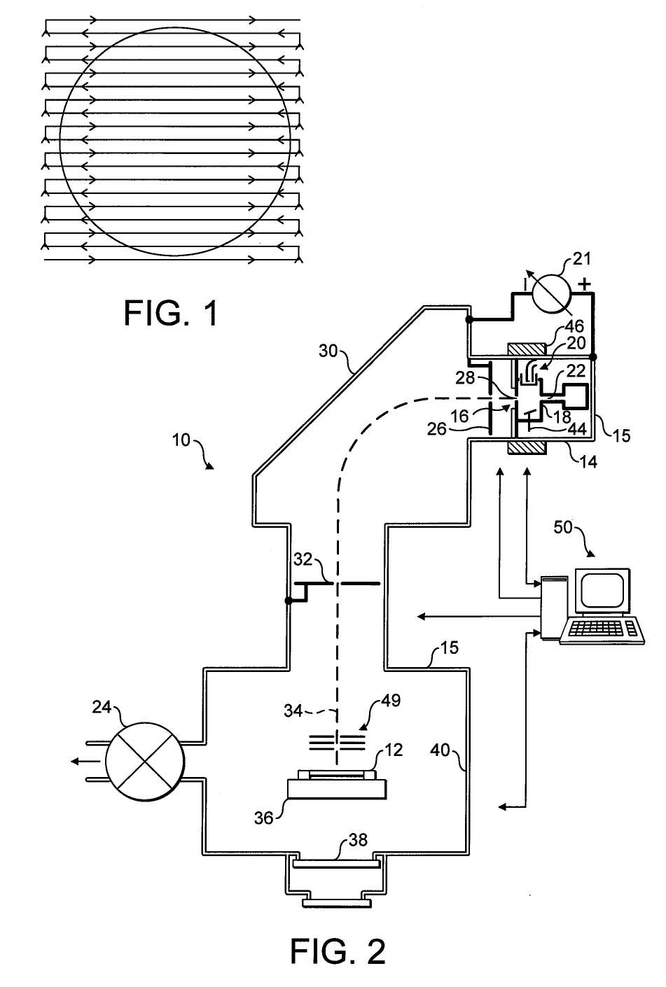

The ion implanter 10 operates under the management of a controller, such as a suitably programmed computer 50. The controller 50 controls scanning of the wafer 12 through the ion beam 34 to effect desired scanning patterns such as raster patterns like that shown in FIG. 1.

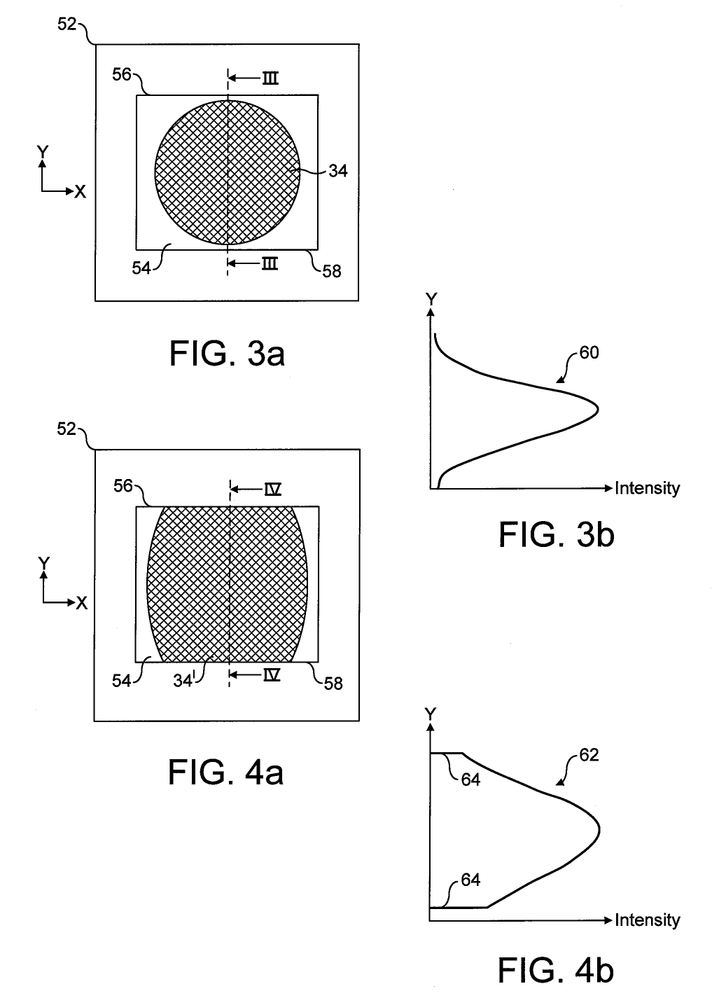

FIG. 3a shows an aperture plate 52 that may be placed on the ion beam path 34. For example, the aperture plate 52 may correspond to one of the electrodes in the lens assembly 49 that is used to accelerate or decelerate ions in the ion beam 34 before reaching the substrate 12. The aperture plate 52 has a conventional rectangular aperture 54 with top and bottom edges 56 and 58 that extend in the fast scan (x axis) direction.

FIG. 3a shows the ion beam 34 passing comfortably through the aperture 54 provided in the aperture plate 52 such that there is clearance between the top edge 56 and the bottom edge 58 of the aperture 54.

FIG. 3a also indicates axes that are used to define the geometry within the ion implanter 10. The ion beam 34 is taken to define the z axis, the y axis is defined as the vertical and the x axis is defined as the horizontal. In these embodiments, raster scans are described that see the ion beam 34 trace a series of scan lines horizontally across the substrate 12, i.e. the x axis defines the fast scan direction and the y axis defines the slow scan direction where the substrate 12 is stepped between successive scan lines.

FIG. 3b shows a profile 60 of the ion beam intensity (i.e. current) taken along a vertical line through the centre of the ion beam 34 at a position immediately downstream of the aperture plate 52. This line is indicated as III-III in FIG. 3a. As the ion beam 34 is not clipped by the aperture plate 52, a profile obtained immediately upstream of the aperture plate 52 would show good correspondence. As can be seen, the profile 60 approximates a Gaussian and may exhibit some asymmetry.

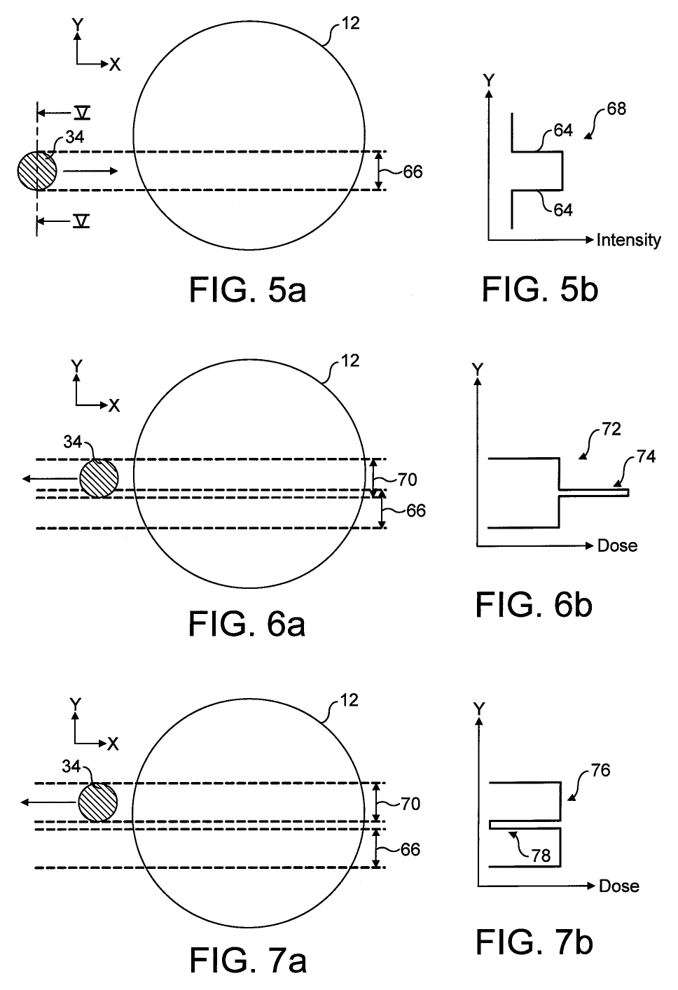

FIGS. 4a and 4b are like FIGS. 3a and 3b, but instead show an enlarged ion beam 34′ that is now taller than the aperture 54. Accordingly, the top and bottom of the ion beam 34 is clipped by the top edge 56 and bottom edge 58 of the aperture 54. The corresponding profile 62 taken along line IV-IV shows the effect of the aperture 54 clipping the ion beam 34. The profile displays sharp edges 64 at its top and bottom. These sharp edges 64 will extend across the profile in the x axis direction for the length of overlap between the ion beam 34 and the aperture 54. Hence, the sharp edges 64 extend in the same direction as the fast scan direction. Such sharp edges 64 extending along the fast scan direction adversely affects uniformity of the dosing, as will be explained with reference to FIGS. 5 to 7.

FIG. 5a shows an ion beam 34 being scanned across a substrate 12 along a first scan line 66. This is effected by scanning the ion beam 34 across a stationary substrate 12 or by moving the substrate 12 relative to a fixed ion beam 34. FIG. 5b shows a hypothetical profile for the ion beam 34 taken vertically along line V-V. The profile shown at 68 is top-hat shaped, this shape being chosen as the ultimate demonstration of the effects of sharp edges 64.

FIG. 6a shows the substrate 12 after the top-hat ion beam 34 has performed two scan lines 66 and 70 of a raster pattern. FIG. 6b shows the dose 72 received by the substrate 12 in the y-axis direction across the two scan lines 66 and 70. As can be seen, a uniform dose is achieved for the parts of the substrate 12 that see only one pass of the ion beam 34, but the small slice of the substrate 12 that sees two passes of the ion beam 34 where the scan lines 66 and 70 overlap has a spike 74 equivalent to twice the dose. Hence, completing a full raster scan like that shown in FIG. 1 in this manner will lead to a substrate 12 with narrow stripes of high dosage, thereby ruining the desired uniformity.

FIGS. 7a and 7b correspond to FIGS. 6a and 6b, but show a situation where a small gap is left between the scan lines 66 and 70. This produces a dose profile 76 that exhibits a sharp dip 78 for the part of the substrate 12 between the scan lines 66 and 70, as shown in FIG. 7b. So, completing a full raster scan like that shown in FIG. 1 in this manner will lead to a substrate 12 with narrow stripes, this time of no dosage, again ruining the desired uniformity.

As will be appreciated, if the two scan lines 66 and 70 can be made to abut perfectly leaving no gap and with no overlap, perfect uniformity may be achieved. However, this is impossible to achieve, meaning that there will always be some overlap or separation leading to striping of the substrate 12.

It will also be understood that the problems of sharp edges 64 caused by the ion beam 34 being clipped by the aperture 54 will also lead to a loss of uniformity in implants. This is because, as explained above, the smoothly varying profile of an unclipped ion beam 34 is used to achieve uniform dosing by overlapping adjacent scan lines. Loss of the smoothly varying tails destroys the compensating effect otherwise provided by the overlapping scan lines.

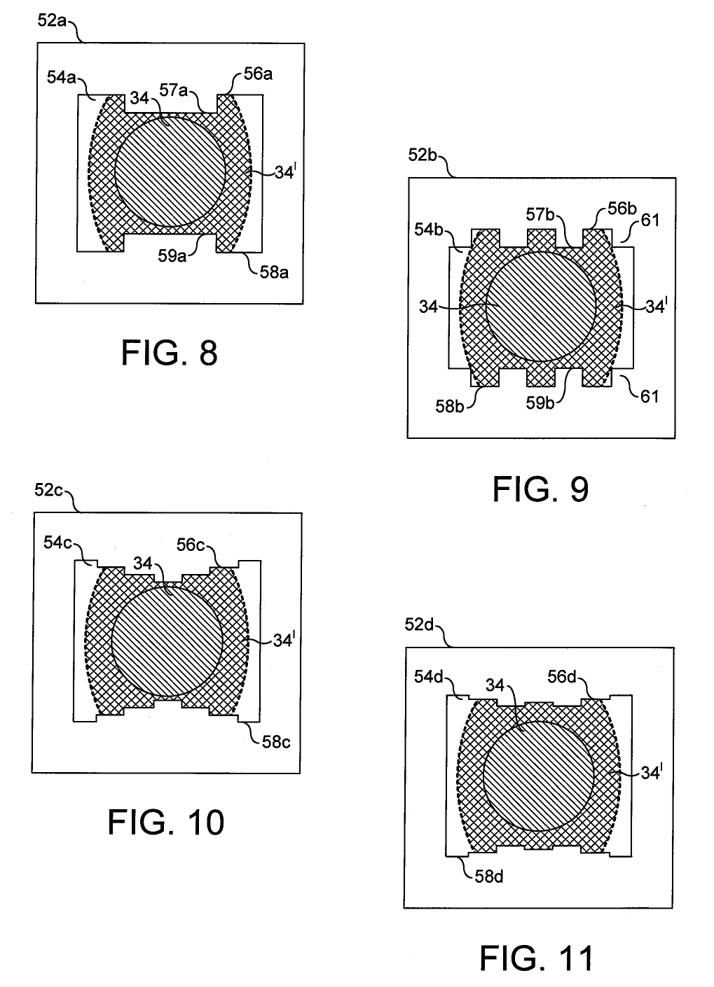

FIGS. 8 to 16 show nine exemplary designs of aperture plates 52 with apertures 54 shaped to reduce the loss of uniformity in the event that an ion beam clips the top and bottom edges of the aperture 54. All the apertures 54 are shaped such that the top edge 56 and bottom edge 58 are not linear in the fast-scan direction (along the x axis). Conveniently, this may be achieved by providing one or more inward projections or salients to the top edge 56 and likewise for the bottom edge 56.

FIG. 8 shows an aperture plate 52a provided with an aperture 54a having a top edge 56a provided with a broad tooth 57a that projects inwardly such that the aperture 54a is at its narrowest midway across in the x-axis direction. This narrowing is more pronounced because the bottom edge 58a is correspondingly shaped, with a matching tooth 59a.

In normal use, the ion beam 34 is intended to pass through the aperture 54a without being clipped as shown by the solid hashed cross-section at 34. However, should the ion beam 34 increase in size, as indicated by the dashed cross-section at 34′, the teeth 57a and 59a provided on the top edge 56a and bottom edge 58a respectively may clip the ion beam 34′. Any single profile taken vertically through the ion beam 34′ at any x-axis position will still display sharp edges like those shown at 64 of FIG. 4b. However, imagining a succession of slices taken while moving along the x-axis to show successive y-axis profiles demonstrates that the y-axis position of the sharp edges varies between two positions corresponding to the base and end of the teeth 57a and 59a. As the ion beam 34 is scanned in the along each scan line, e.g. those shown at 66 and 70 in FIGS. 6a and 7a, the substrate 12 sees these two edge positions and effectively averages the two. Hence, the otherwise single sharp edge of the ion beam 34 is to some extent smeared out by the toothed top and bottom edges 56a and 58a such that a smoother variation is obtained for the top and bottom of the ion beam 34.

FIG. 9 shows a similar aperture plate 52b, this time provided with an aperture 54b having a top edge 56b provided with two teeth 57b and a bottom edge 58b similarly provided with two teeth 59b. Stepped shoulders 61 are also provided in the corners of the aperture 54b that extend inwardly as far as the teeth 57 and 59b. As will be appreciated, this arrangement also provides edges at two positions and so works similarly to the arrangement of FIG. 8. An improvement may be made by varying the depth of the teeth 57b, 59b and the shoulders 61. In this way, three or four edges may be formed in the ion beam 34′ and so will have a greater effect on smearing the otherwise sharp edge of the ion beam 34′.

FIG. 10 shows a further embodiment where the aperture plate 52c is provided with a single stepped projection on its top edge 56c and a similar stepped projection on its lower edge 58c. The steps move progressively inwardly to the vertical centreline of the ion beam 34′ before moving progressively outwardly. As a result, four edges are introduced into the edge of a clipped ion beam 34′.

FIG. 11 shows an aperture plate 52d broadly similar to that of FIG. 10, but here the stepped projections to edges 56d and 58d step inwardly twice before stepping outwardly at the centre and follow the reverse arrangement on the other side of each edge 56d and 58d. Each step in an edge 56d or 58d is chosen to be at a different height, thereby imparting six edges to the ion beam 34′.

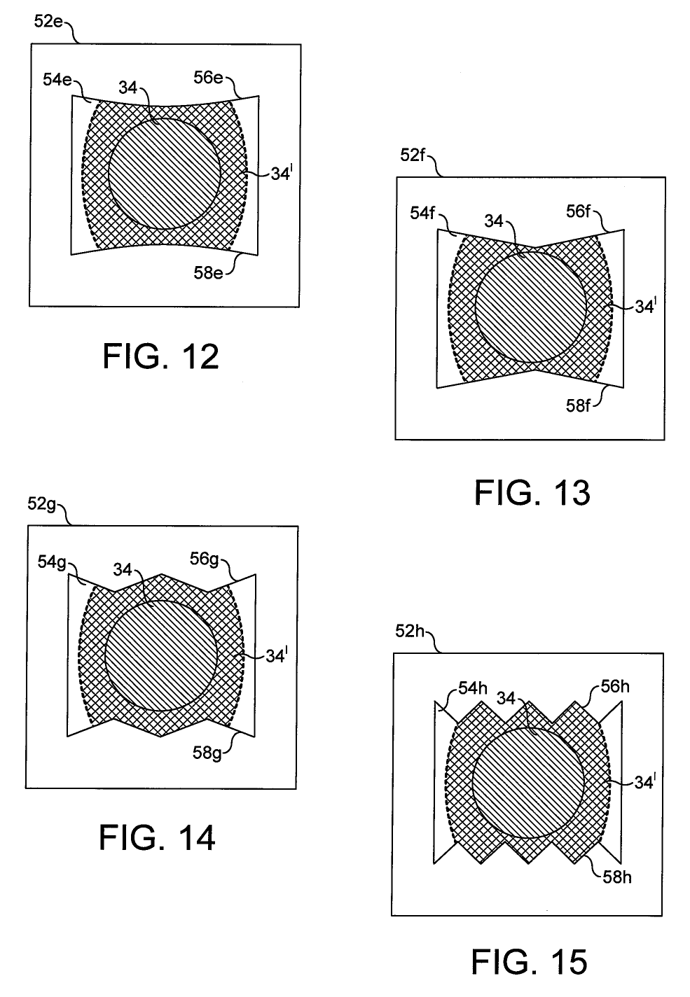

While the above embodiments are effective in addressing problems in uniformity of implant due to clipped ion beams 34′, there remains some residual loss of uniformity due to the stepped nature of the projections. Hence, it is preferred to use projections having sides that extend at an angle to the scanning direction so as to provide a continuous range of the depth of the edges 56 and 58 into the aperture 54. FIG. 12 shows an embodiment of this concept in an aperture plate 52e provided with an aperture 54e defined by an arcuate top edge 56e that projects inwardly such that the aperture 54e is at its narrowest midway across in the x-axis direction. This narrowing is more pronounced because the bottom edge 58e is correspondingly shaped, i.e. with an inward arc.

As before, any single profile taken vertically through the ion beam 34, at any x-axis position will still display sharp edges like those shown at 64 of FIG. 4b. However, imagining a succession of slices taken while moving along the x-axis to show successive y-axis profiles demonstrates this time that the y-axis position of the sharp edges varies continuously, first inwardly as the arcuate projections move inwardly and then outwardly as the arcuate projections move outwardly. As the ion beam 34 is scanned along each scan line, e.g. those shown at 66 and 70 in FIGS. 6a and 7a, the substrate 12 sees all of this range of varying edge positions. Hence, the otherwise sharp edge of the ion beam 34 is smeared out more successfully by the projecting top and bottom edges 56a and 58a such that a smooth variation is retained for the top and bottom of the ion beam 34.

FIG. 13 shows an alternative arrangement where the aperture plate 52f is provided with an aperture 54f with a top edge 56f and a bottom edge 58f shaped to provide inwardly facing v-shaped projections. As will be appreciated, the aperture 54f acts in the same way as aperture 54e, i.e. it smears out smoothly the sharp edges caused by the ion beam 34 being clipped by the top edge 56f and the bottom edge 58f.

As per the stepped arrangement of FIG. 9, multiple projections may be provided on the top edge 56 and bottom edge 58. FIG. 14 shows an aperture plate 52g having an aperture 54g with a top edge 56g provided with two symmetrically-disposed v-shaped projections. Likewise, the bottom edge 58g is also provided with a pair of inwardly-facing v-shaped projections. FIG. 15 shows a still further aperture plate 52h, this time with top and bottom edges 56h and 58h provided with four v-shaped projections. Although the projections are all shown projecting inwardly to the same depth, this need not be the case. The same use of multiple projections per edge 56, 58 may be used with a repeated pattern of the arcuate shape of FIG. 8.

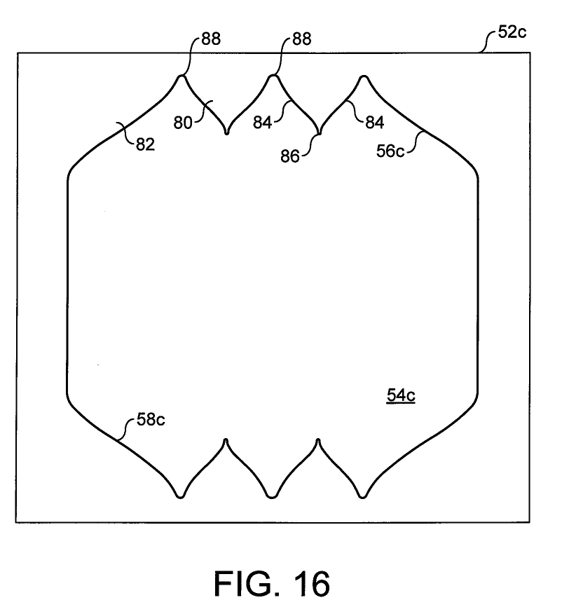

Yet another arrangement is shown in FIG. 16. Here, the aperture plate 52i has an aperture 54i with correspondingly-shaped top and bottom edges 56i and 58i. Each edge 56i, 58i is shaped to have two projections 80 and smoothly curving shoulders 82. The projections 80 are defined by pairs of sinuous edges 84 that meet at a rounded tip 86. The sides 84 curve with the shape of a Gaussian, although rotated through 90° from the vertical such that the projections 80 resemble onion domes (like those seen on churches in Russia). Adjacent projections 80 meet a rounded tip 88, and the outermost two edges 88 blend smoothly with the shoulders 82. The shoulders 82 also share the sinuous shape of the projection's edges 84, although are larger such that they extend further.

The skilled person will appreciate that changes may be made to the above-described embodiment without departing from the scope of the present invention defined by the appended claims.

For example, the number of projections may be varied. The shape of the projections may also be varied, provided the resulting shape still serves to project inwardly. Where multiple projections are used on an edge, these projections need not share a common shape. The depth to which the projections protrude inwardly may be varied according to need. A balance is to be struck between deeper projections having a greater smearing effect and the increased likelihood of deeper projections clipping the ion beam 34.

Although described with respect to linear raster scans like that shown in FIG. 1, the present invention has application in any scanning that results in a pattern formed of adjacent or overlapping scan lines. For example, in parallel implanters several substrates may be held on spokes of a wheel that is spun while being translated such that a series of arcuate scan lines are formed on each substrate.

1. An ion implanter comprising:
an ion source arranged to generate an ion beam;
ion beam optics arranged to guide the ion beam along an ion beam path;
a substrate scanner arranged to scan a substrate relative to the ion beam in a scanning direction substantially transverse to the ion beam path such that the ion beam forms a series of scan lines across the substrate;
and an aperture plate having provided therein an aperture defined by internal edges of the aperture plate, the aperture being positioned on the ion beam path upstream of the substrate scanner, and wherein the aperture is defined in part by an edge extending generally in the scanning direction provided with at least one inwardly-facing projection.

2. The ion implanter of claim 1, wherein the projection is a tooth.

3. The ion implanter of claim 1, wherein the projection has sides that are angled obliquely relative to the scanning direction.

4. The ion implanter of claim 3, wherein the projection is arcuate.

5. The ion implanter of claim 3, wherein the projection is v-shaped.

6. The ion implanter of claim 3, wherein the projection has sinuous edges.

7. The ion implanter of claim 6, wherein the projection is in the shape of an onion dome.

8. The ion implanter of claim 1, wherein the projection is centrally positioned on the edge.

9. The ion implanter of any preceding claim 1, wherein the edge is provided with a plurality of inwardly-facing projections.

10. The ion implanter of claim 9, wherein the edge is provided with a plurality of like inwardly-facing projections.

11. The ion implanter of claim 9, wherein the projections project inwardly to different depths.

12. The ion implanter of claim 1, wherein the aperture is defined in part by a second edge extending generally in the scanning direction that faces the first edge, the second edge also being provided with at least one inwardly-facing projection.

13. The ion implanter of claim 12, wherein the second edge is a mirror image of the first edge.

14. A method of improving uniformity in an implant made by an ion implanter comprising an ion source arranged to generate an ion beam, ion beam optics arranged to guide the ion beam along an ion beam path, a substrate scanner arranged to scan a substrate relative to the ion beam in a scanning direction substantially transverse to the ion beam path such that the ion beam forms a series of scan lines across the substrate, and an aperture plate having provided therein an aperture defined by internal edges of the aperture plate, the aperture being positioned on the ion beam path upstream of the substrate scanner, the method comprising providing the aperture plate with an edge that partly defines the aperture, and that extends generally in the scanning direction but that is provided with at least a portion that extends in a direction other than the scanning direction.

15. The method of claim 14, comprising providing the edge with the portion that extends over 50% of the length of the edge.

16. The method of claim 14, comprising providing the edge with the portion positioned centrally.

17. The method of claim 14, comprising providing the edge with a portion that projects inwardly.

18. The method of claim 17, wherein the projection is a tooth.

19. The method of claim 17, wherein the projection has sides that are angled obliquely relative to the scanning direction.

20. The method of claim 19, wherein the projection is arcuate.

21. The method of claim 19, wherein the projection is v-shaped.

22. The method of claim 19, wherein the projection has sinuous edges.

23. The method of claim 22, wherein the projection is in the shape of an onion dome.

24. The method of claim 17, comprising providing the edge with a plurality of inwardly-facing projections.

25. The method of claim 24, comprising providing the edge with a plurality of like inwardly-facing projections.

26. The method of claim 24, wherein the projections project inwardly to different depths.

27. The method of claim 14, comprising providing the aperture plate with a second edge that partly defines the aperture, and that extends generally in the scanning direction but that is provided with at least a portion that extends in a direction other than the scanning direction.

28. The method of claim 27, wherein the second edge is a mirror image of the first edge.
